(19) United States
(12) Patent Application Publication
(10) Pub. No.: US 2024/0274572 A1
(43) Pub. Date: Aug. 15, 2024

(54) POWER LEADFRAME PACKAGE WITH LEAD SIDEWALL SURFACE THAT IS FULLY SOLDER WETTABLE

(71) Applicant: STMicroelectronics International N.V., Geneva (CH)

(72) Inventor: Jefferson Sismundo TALLEDO, Calamba (PH)

(73) Assignee: STMicroelectronics International N.V., Geneva (CH)

(21) Appl. No.: 18/415,006

(22) Filed: Jan. 17, 2024

Related U.S. Application Data
(60) Provisional application No. 63/444,721, filed on Feb. 10, 2023.

(51) Int. Cl. H01L 23/00; H01L 21/48; H01L 21/56; H01L 23/495

(52) U.S. Cl. CPC H01L 24/84; H01L 21/4842; H01L 21/561; H01L 23/49582; H01L 24/40; H01L 24/97; H01L 21/565; H01L 24/32; H01L 24/73; H01L 24/92; H01L 2224/32245; H01L 2224/40245; H01L 2224/73263; H01L 2224/84947; H01L 2224/92246; H01L 2224/97; H01L 2924/13091

(57) ABSTRACT

An etched leadframe includes separated frame portions, where each frame portion includes an intermediate region interposed between lead and die pad regions. An integrated circuit die is mounted to each die pad region. A clip is mounted to each integrated circuit die, wherein the clip includes a lead mounting portion mounted to the lead region of an adjacent frame portion and a bridge portion extending over the intermediate region of the adjacent frame portion and mounted to the die pad region of the adjacent frame portion. A first cut made through the frame portion of each etched leadframe at the intermediate region separates the lead and die pad regions without severing the bridge portion of each clip. A conductive layer is plated on full sidewalls of the lead and die pad regions exposed by the first cut. A second cut is then made through the bridge portion of each clip.

### CROSS REFERENCE TO RELATED APPLICATIONS

This application claims priority from U.S. Provisional Application for Patent No. 63/444,721, filed Feb. 10, 2023, the disclosure of which is incorporated herein by reference.

### TECHNICAL FIELD

The present invention generally relates to semiconductor packaging and, more particularly, to a power leadframe package with leads having sidewall surfaces that are fully solder wettable.

### BACKGROUND

Reference is made to FIGS. 1A-1L which show steps of a manufacturing process for producing a power leadframe package for an integrated circuit power transistor device.

FIG. 1A—provision is made from a manufacturer or supplier of an etched leadframe 12 that includes die pad portions 14 and lead portions 16. The die pad portions 14 and lead portions 16 are separated from each other by spaces defined by a half-etched opening 20 at the bottom of the leadframe and a through opening 22 at the top of the leadframe.

FIG. 1B—an integrated circuit die 24 is mounted to the upper surface of each die pad portion 14. This attachment may, for example, be made using a suitable die attachment mechanism 26. As an example, a die attach film, a layer of adhesive, or a layer of solder could be used for attachment.

FIG. 1C—bonding pads at an upper surface of the integrated circuit die 24 are electrically connected to upper surfaces at the distal ends 30 of the lead portions 16 of the leadframe 12 by bonding wires 28.

FIG. 1—the assembly of the leadframe 12, integrated circuit dies 24 and bonding wires 28 is then positioned within the open cavity 34 of a mold 36.

FIG. 1E—a resin encapsulant material is injected into the open cavity 34 and cured to form an encapsulating body 38 that encapsulates the assembly of the leadframe 12, integrated circuit dies 24 and bonding wires 28, including filling the half-etched openings 20 and through openings 22 of the leadframe 12.

FIG. 1F—the encapsulated assembly is removed from the mold 36.

FIG. 1G—a saw (schematically represented by arrow 40) is used to partially cut through the lead portions 16 of the leadframe 12 to form a channel 42. The depth of the channel 42 may, for example, comprise between 40 and 60 percent of the overall thickness of the lead portions 16 of the leadframe 12.

FIG. 1H—an electroless plating process is then performed to plate a tin layer 44 on the exposed surfaces of the leadframe 12. These exposed surfaces would include, for example, the lower surfaces of the die pad portions 14 of the leadframe 12, the lower surfaces of the lead portions 16 of the leadframe 12, and the sidewalls and bottom of the channel 42 formed in the lead portions 16 of the leadframe 12.

FIG. 1I—a saw (schematically represented by arrow 46) is used to completely cut through the encapsulated assembly and form a separation opening 48. This saw cut is aligned with the location of the saw cut which formed the channel 42. This cutting operation effectuates a singulation of the encapsulated assembly into a plurality of power leadframe packages 50. A width of the saw cut performed by saw 46 is smaller than a width of the saw cut performed by saw 40.

FIG. 2 shows a cross-sectional view of the power leadframe package 50. It will be noted that the flank area 54 of the leads 52 (i.e., their sidewall surfaces) for the power leadframe package 50 includes a wettable flank portion 56 (covered by the tin layer 44) and a non- wettable flank portion 58 (exposed by the saw cut in the step shown in FIG. 1I). As a result, this power leadframe package 50 does not present a fully-wettable sidewall for the package leads 52.

There is a need in the art to address this deficiency and provide a power leadframe package with leads having sidewall surfaces that are fully solder wettable.

### SUMMARY

In an embodiment, a method comprises: providing an etched leadframe that includes a plurality of frame portions, wherein the frame portions are separated from each other by spaces, and wherein each frame portion includes an intermediate region interposed between a lead region and a die pad region; mounting an integrated circuit die to an upper surface of each frame portion at said die pad region; mounting a chip mounting portion of a metal clip to each integrated circuit die, said metal clip further including a lead mounting portion mounted to the lead region of an adjacent frame portion, and said metal clip still further including a bridge portion extending over said intermediate region of said adjacent frame portion and mounted to the die pad region of said adjacent frame portion; performing a first operation to cut through the frame portion of each etched leadframe at said intermediate region to separate the lead region and die pad region without severing the bridge portion of each metal clip; plating a conductive layer on full sidewalls of the lead region and die pad region exposed by the first operation to cut; and performing a second operation to cut through the bridge portion of each metal clip.

In an embodiment, a power leadframe integrated circuit package comprises: a leadframe including a lead region and a die pad region separated by a space; an integrated circuit die mounted to an upper surface of the die pad region; a first metal clip having a chip mounting portion mounted to the integrated circuit die, said first metal clip further including a lead mounting portion mounted to the lead region and a first residual bridge portion; a second metal clip including a second residual bridge portion mounted to the die pad region; an encapsulating body encapsulating the leadframe, the integrated circuit die and the first and second metal clips; wherein said encapsulating body has a first peripheral sidewall at which an end of said first residual bridge portion is exposed and has a second peripheral sidewall, opposite said first peripheral sidewall, at which an end of said second residual bridge portion is exposed; wherein a sidewall of the lead region is exposed at said first peripheral sidewall of the encapsulating body, and wherein a sidewall of the die pad region is exposed at said second peripheral sidewall of the encapsulating body; and a plating layer on all of said sidewall of the lead region and all of said sidewall of the die pad region.

### BRIEF DESCRIPTION OF THE DRAWINGS

For a better understanding of the embodiments, reference will now be made by way of example only to the accompanying figures in which:

FIGS. 1A-1I show steps of a manufacturing process for producing a power leadframe package for an integrated circuit power transistor device;

FIG. 2 shows a power leadframe package produced by the process of FIGS. 1A-1L;

FIGS. 3A-3I show steps of a manufacturing process for producing a power leadframe package for an integrated circuit power transistor device;

FIG. 4 shows a power leadframe package produced by the process of FIGS. 3A-3L;

FIGS. 5A-5D show top views at the stage of the manufacturing process shown at steps corresponding to FIGS. 3A, 3B, 3C and 3I, respectively; and

FIG. 6 is a perspective view of an assembly of a leadframe, integrated circuit die and clip at the stage of the manufacturing process shown at the step corresponding to FIG. 3C.

### DETAILED DESCRIPTION

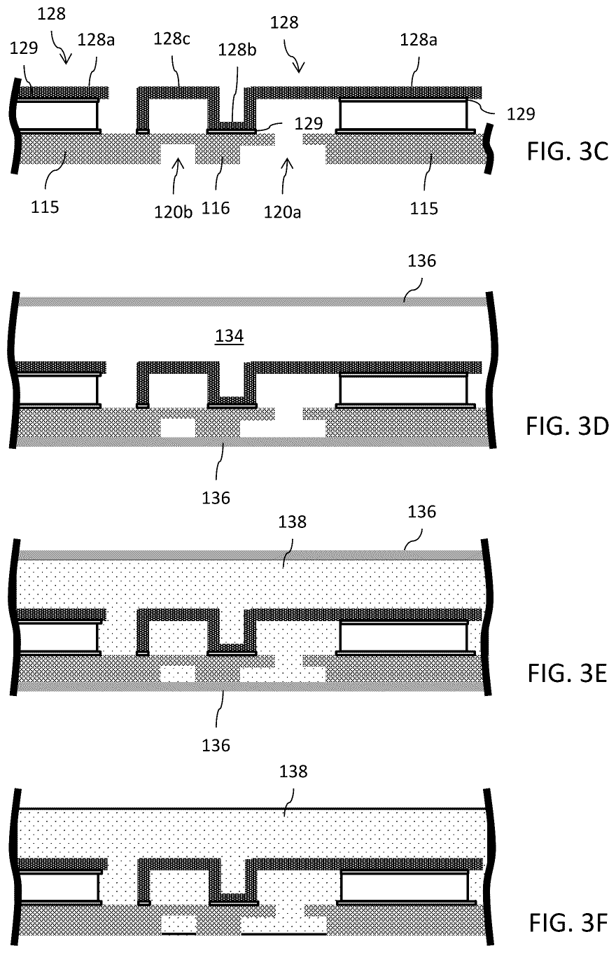

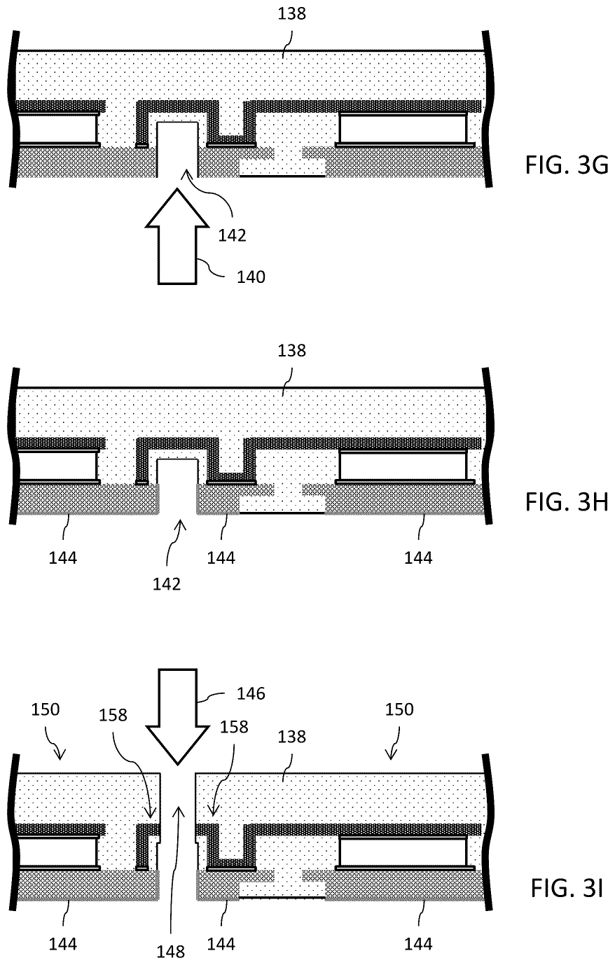

Reference is made to FIGS. 3A-3I which show steps of a manufacturing process for producing a power leadframe package for an integrated circuit power transistor device.

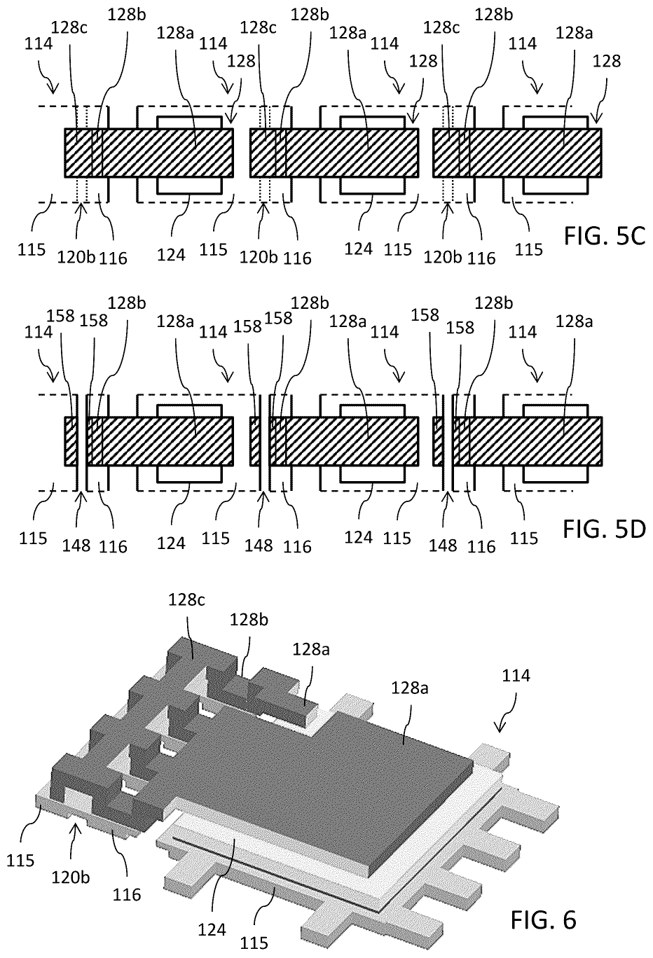

FIG. 3A—provision is made from a manufacturer or supplier of an etched leadframe 112 that includes frame portions 114. The frame portions 114 are separated from each other by spaces defined by a half-etched opening 120a at the bottom of the leadframe and a through opening 122 at the top of the leadframe. A further half-etched opening 120b at the bottom of the leadframe is optionally provided at an intermediate region (of each frame portion 114) located between a die pad region 115 and lead region 116 of each frame portion 114. It will be noted, however, that the optionally provided further half-etched opening 120b does not separate the die pad region 115 and lead region 116. FIG. 5A shows a top view of a portion of the leadframe 112 at the stage of the manufacturing process shown in FIG. 3A.

FIG. 3B—an integrated circuit die 124 is mounted to the upper surface of each frame portion 114 at the die pad region 115. This attachment may, for example, be made using a suitable die attachment mechanism 126. As an example, a die attach film, a layer of adhesive, or a layer of solder could be used for attachment. FIG. 5B shows a top view of a portion of the leadframe 112 with attached integrated circuit dies 124 at the stage of the manufacturing process shown in FIG. 3B.

FIG. 3C—bonding pads at an upper surface of the integrated circuit die 124 mounted to the die pad region 115 of one frame portion (for example, portion 114a) of the lead frame 112 are electrically connected to upper surfaces at the lead regions 116 of an adjacent frame portion (for example, portion 114b) of the leadframe 112 and further to the die pad region 115 of that adjacent frame portion 114b of the leadframe 112 using a metal clip 128. The metal clip 128 comprises a strip of material that is bent into a shape that includes a chip mounting portion 128a, a lead mounting portion 128b and a bridge portion 128c. The chip mounting portion 128a is essentially a flat portion having a lower surface that is electrically connected by a solder material 129 to bonding pads of the integrated circuit die 124. The lead mounting portion 128b is essentially an L-shaped portion having a vertical leg and a horizontal leg; where the vertical leg extends downwardly from the chip mounting portion 128a towards the leadframe 112 and the horizontal leg has a lower surface that is electrically connected by a solder material 129 to the upper surface at the lead region 116 of the adjacent frame portion 114b of the leadframe 112. The bridge portion 128c is essentially an upside-down U-shaped portion having a first vertical leg, a horizontal leg and a second vertical leg; where the first vertical leg extends upwardly from the horizontal leg of the lead mounting portion 128b, the horizontal leg extends from the first vertical leg to bridge over the location of the further half-etched opening 120b, and the second vertical leg extends downwardly from the horizontal leg and has an end surface electrically connected by a solder material 129 to the upper surface at the die pad region 115 of the adjacent frame portion 114b of the leadframe 112. FIG. 5C shows a top view of a portion of the leadframe 112 with attached integrated circuit dies 124 and mounted metal clips 128 at the stage of the manufacturing process shown in FIG. 3C. FIG. 6 shows a perspective view of an assembly of the leadframe 112, integrated circuit die 124 and clip 128 at the stage of the manufacturing process shown in FIG. 3C.

It will be noted that other bonding pads of the integrated circuit die 124 may be electrically connected to upper surfaces at the distal ends of the lead regions 116 of the leadframe 12 by bonding wires (not explicitly shown) or through use of one or more other clips 128 as shown in FIG. 6.

FIG. 3D—the assembly of the leadframe 112, integrated circuit dies 124 and clips 128 is then positioned within the open cavity 134 of a mold 136.

FIG. 3E—a resin encapsulant material is injected into the open cavity 134 and cured to form an encapsulating body 138 that encapsulates the assembly of the leadframe 112, integrated circuit dies 124 and clips 128, including filling the half-etched openings 120a, 120b and through openings 122 of the leadframe 112.

FIG. 3F—the encapsulated assembly is removed from the mold 136.

FIG. 3G—a saw (schematically represented by arrow 140) is used to partially cut into the encapsulated assembly from a lower surface thereof to form a channel 142. This saw cut is aligned with the half-etched opening 120b and passes completely through the leadframe 112 to separate the die pad region 115 and lead region 116 of each frame portion 114. The depth of the channel 142 made by the saw cut is sufficient to remove a portion of the cured resin encapsulant material that is located between the first and second vertical legs of the bridge portion 128c of the metal clip 128 without severing the horizontal leg which extends between the first and second vertical legs. As the presence of the half-etched opening 120b is optional, it will be understood that in cases where the half-etched opening 120b is not present to assist with saw 140 alignment that other means must be used to ensure that the saw cut is accurately positioned to form channel 142 at the location between the first and second vertical legs of the bridge portion 128c of the metal clip 128.

FIG. 3H—a plating process is then performed to plate a tin layer 144 on the exposed surfaces of the leadframe 112. These exposed surfaces would include, for example, the lower surfaces of the die pad region 115, the lower surfaces of the lead region 116 of each frame portion 114 of the leadframe 12, and the sidewalls of the die pad region 115 and lead region 116 at the channel 142.

It will be noted that the metal clips 128 provide electrical connections among and between all of the frame portions 114 of the etched leadframe 112. An advantage of this is that all frame portions 114 can be placed at the same electrical potential in connection with the performance of an electroplating process in the manufacturing step of FIG. 3H to deposit the tin layer 144.

FIG. 3I—a saw (schematically represented by arrow 146) is used to completely cut through the encapsulated assembly from an upper surface thereof and form separation opening 148. This saw cut is aligned with the location of the saw cut which formed the channel 142. This cutting operation effectuates a singulation of the encapsulated assembly into a plurality of power leadframe packages 150. The saw cut is made through the horizontal leg of the bridge portion 128c of the metal clip 128, and thus leaves opposed residual parts 158 of the bridge portion 128c with cut ends of the horizontal leg of the bridge portion 128c exposed at peripheral side surfaces of each power leadframe package 150. FIG. 5D shows a top view (without the encapsulant present) of a portion of the leadframe 112 with attached integrated circuit dies 124 and mounted metal clips 128 at the stage of the manufacturing process shown in FIG. 3I. A width of the saw cut performed by saw 146 is smaller than a width of the saw cut performed by saw 140.

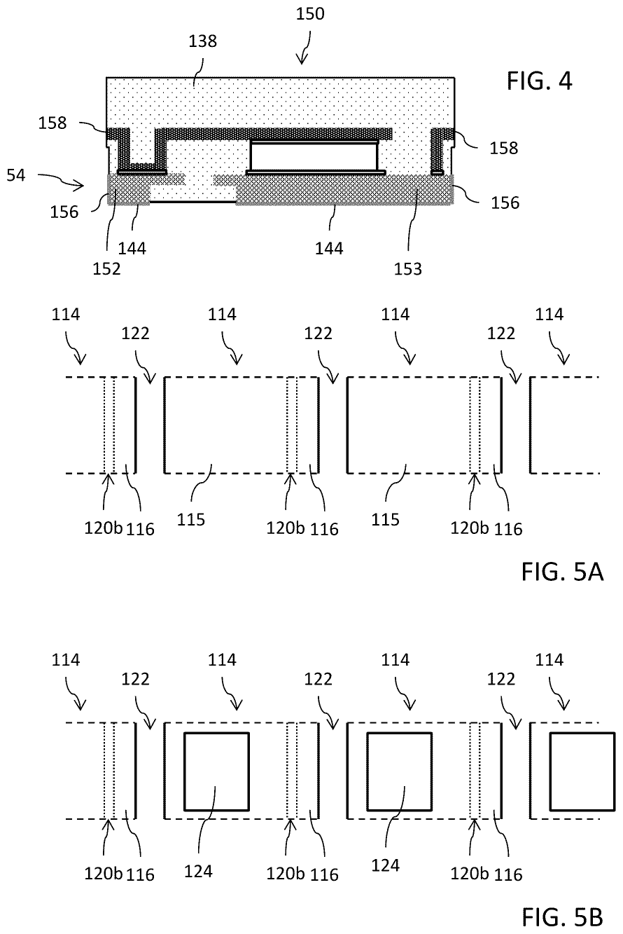

FIG. 4 shows a cross-sectional view of the power leadframe package 150. It will be noted that the flank area 154 of the leads 152 and die pad 153 for the power leadframe package presents a fully wettable flank portion 156 (covered by the tin layer 144). The entire sidewall surfaces for the package leads 152 and die pad 153 were exposed by the saw cut in the step shown in FIG. 3G and as a result the electroplating process covered the entire sidewall surfaces with the tin layer 144. This power leadframe package 150 accordingly includes a fully-wettable sidewall for the package leads 152 and die pad 153. The cut ends of the horizontal leg of the bridge portion 128c which are exposed at peripheral side surfaces of each power leadframe package 150 provide a clear indication that the horizontal leg of the bridge portion 128c of the metal clip 128 was present during manufacturing and severed during the singulation process. The lateral offset of the peripheral sidewall of the package relative to the fully-wettable sidewall for the package leads 152 and die pad 153 provides a clear indication of the use of two separate cuts during manufacturing.

In the context of FIG. 4, the included residual parts 158 are positioned (and exposed) at opposite peripheral side surfaces of the encapsulating body. One of the residual parts 158 is part of a (first) metal clip that is mounted to the integrated circuit die of the illustrated package 150 and the other of the residual parts 158 is part of a (second) metal clip that is mounted to the integrated circuit die another (not illustrated) illustrated package 150 (see, FIG. 3I) severed from each other during the singulation process. The fully wettable sidewall for the package leads 152 and the fully wettable sidewall for die pad 153 are provided at the corresponding opposite peripheral side surfaces of the encapsulating body.

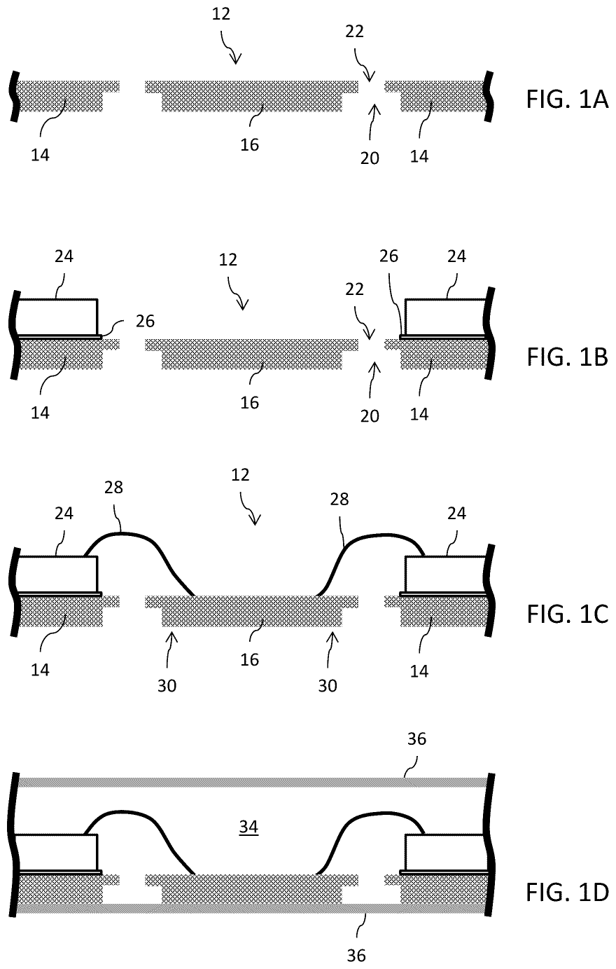

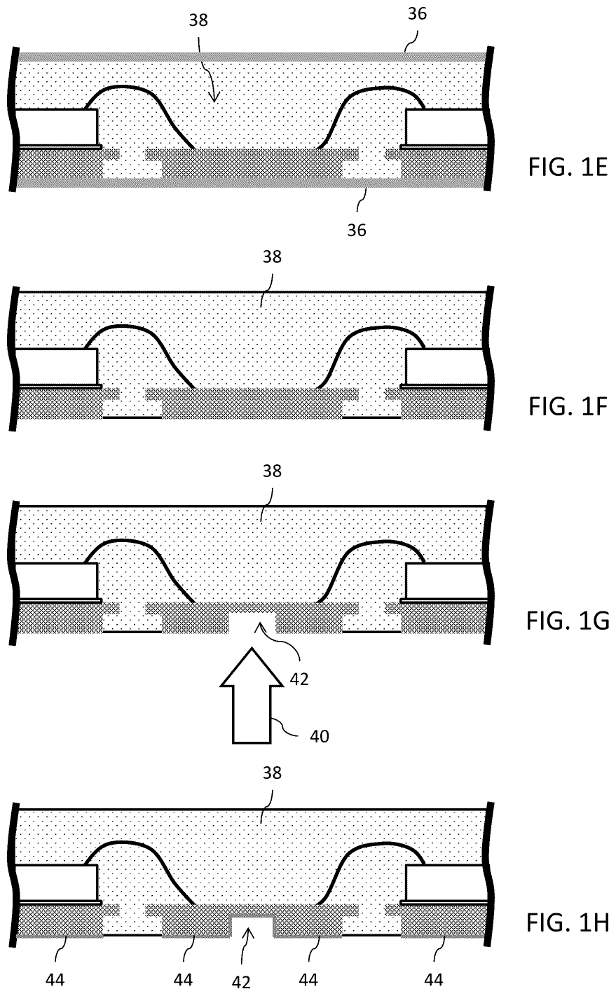

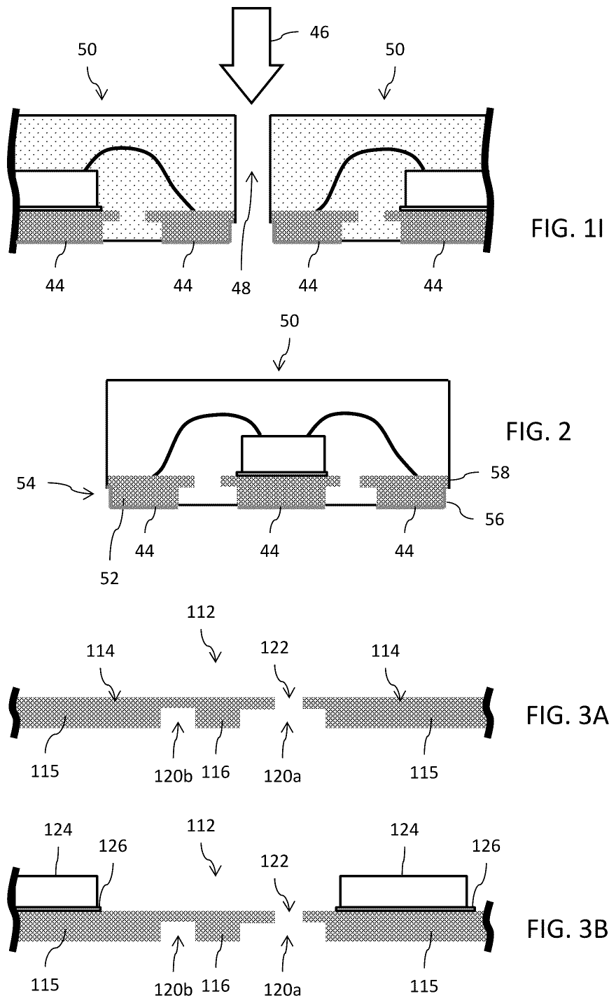

In a preferred embodiment, the integrated circuit die 124 is a power metal oxide semiconductor field effect transistor (MOSFET) and the one or more metal clips 128 included in the package 150 support a high current capacity associated with the source/drain region of the MOSFET. In particular, the opening 148 severed die pad region 115 provides a current conduction lead (die pad) for the drain terminal of the MOSFET and the opening 148 severed lead region 116 along with metal clip 128 provides a current conduction lead for the source terminal of the MOSFET. It will, of course, be understood that a lead structure of the leadframe 112 for the gate terminal (see FIG. 6) would be present and that lead structure could, for example, be electrically connected to a gate bonding pad of the integrated circuit die 124 using convention wire bonding (like that shown in FIG. 1C). Alternatively, a smaller (for example, narrower) metal clip 128 could be used for the electrical connection of the gate bonding pad to the lead structure of the leadframe 112 (as shown in FIG. 6).

With reference to the perspective view shown in FIG. 6, it will also be noted that clip 128 can include multiple chip mounting portions 128a, lead mounting portions 128b and bridge portions 128c. In this case, for example, the larger chip mounting portion 128a is configured for connection to a power transistor source/drain region of the integrated circuit die 124 while the smaller chip mounting portion 128a is configured for connection to a transistor gate region of the integrated circuit die 124.

Advantages of the method of FIGS. 3A-3I and the power leadframe package 150 of FIG. 4 include, at least, the following: a) the entire sidewall surface for the package leads 152 is solderable and/or solder wettable; b) a stronger solder joint can be made between the power leadframe package 150 and a supporting substrate (such as a printed circuit board); c) the presence of side solder required for automated solder inspection is ensured; d) a simple electroplating process is supported for depositing the tin layer, and this is less expensive that the use of electroless plating; and e) there is an improved performance in terms of lead anchoring.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A method, comprising:
providing an etched leadframe that includes a plurality of frame portions, wherein the frame portions are separated from each other by spaces, and wherein each frame portion includes an intermediate region interposed between a lead region and a die pad region;
mounting an integrated circuit die to an upper surface of each frame portion at said die pad region;
mounting a chip mounting portion of a metal clip to each integrated circuit die, said metal clip further including a lead mounting portion mounted to the lead region of an adjacent frame portion, and said metal clip still further including a bridge portion extending over said intermediate region of said adjacent frame portion and mounted to the die pad region of said adjacent frame portion;
performing a first operation to cut through the frame portion of each etched leadframe at said intermediate region to separate the lead region and die pad region without severing the bridge portion of each metal clip;
plating a conductive layer on full sidewalls of the lead region and die pad region exposed by the first operation to cut; and
performing a second operation to cut through the bridge portion of each metal clip.

2. The method of claim 1, wherein performing the first operation to cut comprises sawing.

3. The method of claim 1, wherein performing the second operation to cut comprises sawing.

4. The method of claim 1, wherein plating the conductive layer comprises performing an electroplating.

5. The method of claim 4, wherein electroplating comprises applying a potential to the lead regions and die pad regions of all frame portions of the leadframe through an electrical connection provided by the metal clips.

6. The method of claim 1, wherein plating the conductive layer further comprises plating the conductive layer on bottom surfaces of the lead regions and die pad regions of all frame portions of the leadframe.

7. The method of claim 1, further comprising encapsulating an assembly formed by the etched leadframe, mounted integrated circuits and mounted metal clips in an encapsulating material forming an encapsulating body.

8. The method of claim 7, wherein performing the first operation to cut further cuts through a portion of the encapsulating material forming the encapsulating body that is located between the bridge portion of each metal clip and the intermediate region of the frame portions of the leadframe.

9. The method of claim 8, wherein performing the first operation to cut comprises applying the cut to a lower surface of the encapsulating body at the intermediate region.

10. The method of claim 7, wherein performing the second operation to cut further cuts through a portion of the encapsulating material forming the encapsulating body that is located between the bridge portion of each metal clip and an upper surface of the encapsulating body.

11. The method of claim 10, wherein performing the second operation to cut comprises applying the cut to the upper surface of the encapsulating body.

12. The method of claim 1, wherein providing the etched leadframe further comprises providing a channel at a lower surface of each frame portion at the intermediate region.

13. The method of claim 12, wherein performing the first operation to cut comprises aligning the first operation to cut with the channel at the lower surface of each frame portion.

14. A power leadframe integrated circuit package, comprising:
a leadframe including a lead region and a die pad region separated by a space;
an integrated circuit die mounted to an upper surface of the die pad region;
a first metal clip having a chip mounting portion mounted to the integrated circuit die, said first metal clip further including a lead mounting portion mounted to the lead region and a first residual bridge portion;
a second metal clip including a second residual bridge portion mounted to the die pad region;
an encapsulating body encapsulating the leadframe, the integrated circuit die and the first and second metal clips;
wherein said encapsulating body has a first peripheral sidewall at which an end of said first residual bridge portion is exposed and has a second peripheral sidewall, opposite said first peripheral sidewall, at which an end of said second residual bridge portion is exposed;
wherein a sidewall of the lead region is exposed at said first peripheral sidewall of the encapsulating body, and wherein a sidewall of the die pad region is exposed at said second peripheral sidewall of the encapsulating body; and
a plating layer on all of said sidewall of the lead region and all of said sidewall of the die pad region.

15. The power leadframe integrated circuit package of claim 14, wherein said integrated circuit die comprises a power metal oxide semiconductor field effect transistor (MOSFET) and wherein said first metal clip provides a high current capacity associated with a source region or drain region of the MOSFET.

16. The power leadframe integrated circuit package of claim 14, wherein the plating layer is a tin layer.

17. The power leadframe integrated circuit package of claim 14, wherein the plating layer further extends on lower surfaces of the lead region and die pad region.

18. The power leadframe integrated circuit package of claim 14, wherein the second residual bridge portion is a singulation severed part of the first metal clip for another power leadframe integrated circuit package.

19. The power leadframe integrated circuit package of claim 14, wherein the first residual bridge portion is a singulation severed part of the second metal clip for another power leadframe integrated circuit package.
